(19) United States
(12) Patent Application Publication
(10) Pub. No.: US 2008/0164551 A1
(43) Pub. Date: Jul. 10, 2008

(54) IMAGE SENSOR

(76) Inventor: Young-Je Yun, Gyeonggi-do (KR)

Correspondence Address: SHERR & NOURSE, PLLC, 620 HERNDON PARKWAY, SUITE 200, HERNDON, VA, 20170, US

(21) Appl. No.: 11/964,533

(22) Filed: Dec. 26, 2007

(30) Foreign Application Priority Data
Dec. 28, 2006 (KR) 10-2006-0136969

(51) Int. Cl. H01L 31/0232; H01L 31/18

(52) U.S. Cl. 257/432; 438/70; 257/E31.127; 257/E21.533

(57) ABSTRACT

Embodiments relate to an image sensor, and for directly manufacturing microlenses on color filter layers without forming a separate planarization layer, by forming the color filter layers having a relatively even step. According to embodiments, a method may include forming an interlayer dielectric layer on a semiconductor substrate formed with a plurality of photo diodes, forming color filter layers on the interlayer dielectric layer, forming a sacrifice layer on the whole surface including the color filter layers, making the steps of the color filter layers even by etching the upper surfaces of the color filter layers and the sacrifice layer, and forming microlenses on the color filter layers.

The present application claims priority under 35 U.S.C. 119 and 35 U.S.C. 365 to Korean Patent Application No. 10-2006-0136969 (filed on Dec. 28, 2006), which is hereby incorporated by reference in its entirety.

### BACKGROUND

An image sensor may be a semiconductor device that converts an optical image into an electrical signal, and can largely be divided two types of devices. The first type may be a charge coupled device (CCD) image sensor device and the second may be a complementary metal oxide semiconductor (CMOS) image sensor device.

An image sensor may be configured of a pixel unit and may include a photo diode, that may sense irradiated light, and a logic circuit unit, that may process the light sensed from the photo diode into an electrical signal so as to represent the light as data. In general, an increased amount of light received at the photo diode results in better photo sensitivity characteristics of the image sensor.

To enhance such photo sensitivity, a technique which enlarges a fill factor that the area of a photo diode occupies among the entire area of the image sensor or condenses light into the photo diode by changing the optical path incident on the region other than the photo diode, may be used.

One condensing technique may be to form a microlens. In other words, a convex microlens may be formed on an upper portion of the photo diode using material having good light transmittance. The microlens may refract the path of incident light, which may increase the amount of light irradiated to the photo diode region.

In this case, the light horizontal to the optical axis of the microlens may be refracted by the microlens so that the focus thereof may be formed at a predetermined position on the optical axis.

An image sensor may include a photo diode, an interlayer dielectric layer, a color filter layer, and a micro lens, among other parts.

The photo diode may perform the function sensing and converting light into an electrical signal, and the interlayer dielectric layer may insulate each metal wiring. The color filter layer may include RGB three primary colors of light, and the micro lens may perform condense light into the photo diode.

Hereinafter, a method for manufacturing a related art image sensor will be described.

FIG. 1 is a schematic cross-sectional drawing of an image sensor of the related art.

Referring to FIG. 1, interlayer dielectric layer 20 may be formed on semiconductor substrate 10 formed with a plurality of photo diodes 40, and RGB color filter layers 30, each corresponding to locations of the plurality of photo diodes 40, which may be formed on interlayer dielectric layer 20.

Planarization layer 25, for planarizing any uneven surface layers of color filter layers 30 may be formed on color filter layers 30, and microlenses 50 each corresponding to the plurality of photo diodes 40 and color filter layers 30 may be formed on planarization layer 25.

Microlenses 50 should be formed in a convex lens pattern to collect light to respective photo diodes. Microlenses may be patterned by applying a photo etching process.

The related art image sensor may be formed in a structure where planarization layer 25 may be thickly formed on a surface, for example, the whole surface, including the color filter layers. This may overcome an uneven step (i.e slight variation in the surface) of the color filter layers. However, such a structure may have a disadvantage that as the size of the pixel unit of the image sensor is reduced, the thickness of the planarization layer may become relatively thick. This may deteriorate the performance sensing light signal. It may also have a problem that owing to the thickness difference between the pixel unit where both the color filter layers and the planarization layer may be formed and a logic circuit unit where both the color filter layers and the planarization layer are not formed, a stripe such as striation may occur during a coating process for forming the microlenses. Additionally, the microlenses should be preferably be formed thinly to compensate for the focal length by the thickness of the planarization layer so that the process margin thereof may be reduced.

FIG. 2 is a schematic cross-sectional drawing of another related art image sensor.

Referring to FIG. 2, a process method that may minimize steps by optimizing a color filter layer formation process to directly form microlenses 50 on color filter layers 30 without planarization layer 25 may be performed. However, in this sensor, among the three colors of color filter layers 30, another problem may occur. Specifically, a physically inevitable curved surface may be formed during the process coating a color filter photo resist added when the pattern of a partial color is formed.

FIGS. 3e to 3c are process cross-sectional drawings showing a method for forming a related art image sensor.

Referring to FIG. 3a, blue color filter layer 30B and red color filter layer 30R may be formed on interlayer dielectric layer 20. Green color filter photo resist 60 may be coated to form green color filter layer 30G. A step difference may occur between the portion where the blue and red color filter layers may be formed and the portion where the blue and red color filter layers are not formed. If the green color filter photo resist is coated, the surface of the portion where the blue and red color filter layers are not formed may have a concave curved surface.

Referring to FIG. 3b, if a pattern is formed, green color filter layer 30G, may be formed having a concave curved upper surface. The curved surface may become an important cause modifying a microlens pattern to be formed thereon Deterioration of image characteristics may therefore occur.

Referring to FIG. 3c, although a reactive ion etching etch back process may be additionally performed, the etching selectivity between the color filter layer patterns may still be insufficient to be etched in the same shape as the previous shape so that the step difference between the color filter layer patterns may still exist and the curved surface of the green color filter layer may also still exists.

Therefore, the planarization layer interposed between the color filter layers and the microlenses should preferably have a structure where the thickness thereof may be thick and the focal length thereof may be compensated by the thickness of the planarization layer. As a result, a method, which removes the planarization layer and intends to directly form the microlenses on the color filter layers, has been proposed.

However, the related art method for manufacturing an image sensor may have various problems. For example, since a step difference may occur between the R, G, and B color filter layer patterns, the surfaces thereof may be uneven. Although the RIE etch back process may be additionally performed to remove the uneven step, the difference of the etching selectivity between the R, G, and B color filter layer patterns may be small so that the uneven step may be etched as it is. Hence, surfaces thereof may not be evenly formed.

### SUMMARY

Embodiments relate to an image sensor, and more particularly to a method for manufacturing an image sensor including a color filter having an even step.

Embodiments relate to a method for manufacturing an image sensor capable of directly forming microlenses on color filter layers without forming a separate planarization layer, by making the step of the color filter layers even to planarize the surface of the color filter layers.

According to embodiments, a method for manufacturing an image sensor may include forming an interlayer dielectric layer on a semiconductor substrate formed with a plurality of photo diodes, forming color filter layers on the interlayer dielectric layer, forming a sacrifice layer on a surface, for example, the whole surface, including the color filter layers, making the steps of the color filter layers even by etching the upper surfaces of the color filter layers and the sacrifice layer, and forming microlenses on the color filter layers.

### DRAWINGS

FIG. 1 is a schematic cross-sectional drawing of a related art image sensor.

FIG. 2 is a schematic cross-sectional drawing of a related art image sensor.

FIGS. 3e to 3c are process cross-sectional drawings showing a method for forming a related art image sensor.

FIGS. 4a to 4d are process cross-sectional drawings showing a method for forming an image sensor according to embodiments.

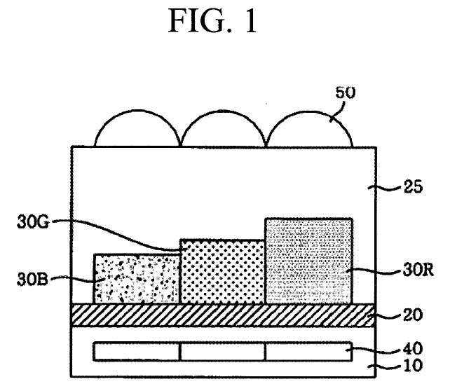

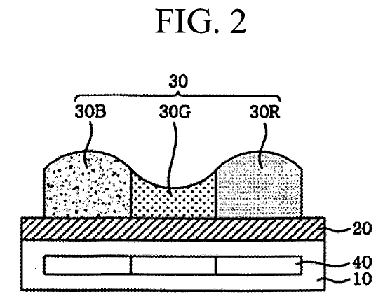

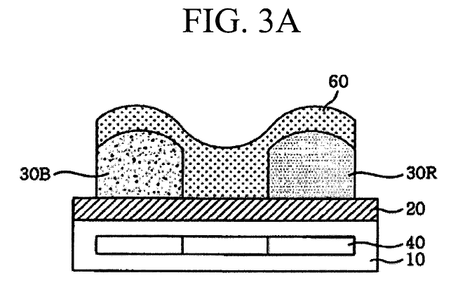

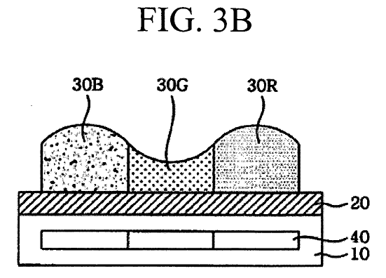

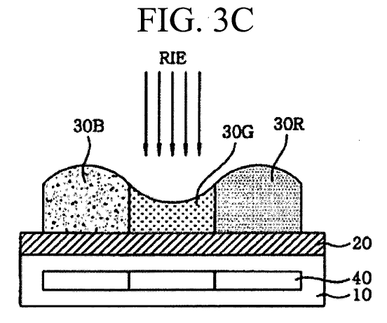

### DESCRIPTION

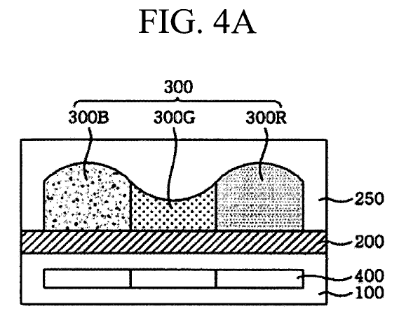

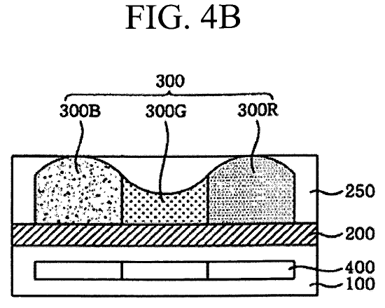

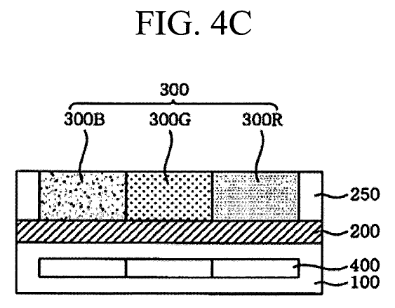

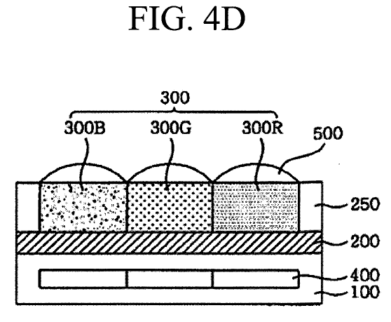

Referring to FIG. 4d, an interlayer dielectric layer 200 may be formed on a semiconductor substrate 100 formed with a plurality of photo diodes 400.

Color filter layers 300 each corresponding to a location of respective ones of the plurality of photo diodes 400 may be formed on the interlayer dielectric layer 200. The color filter layers may be formed in a mosaic form, wherein red R or blue B may be alternated with green G.

According to embodiments, the surface steps of the respective R, G, and B color filter layer patterns may be the same so that the upper surfaces of the color filter layers may be substantially flat.

According to embodiments, microlenses 500, which may be laid out in a predetermined pattern may be directly formed on the color filter layers without adding a separate insulating layer. The microlenses may be formed to correspond to the uppers of the photo diodes and the color filter layers so that they may focus the light emitted from an object on photo diodes 300.

Such a method for manufacturing the image sensor will be described in additional detail as follows.

Referring to FIG. 4a, impurity ions may be selectively implanted into the semiconductor substrate 100 to form R, G, and B photo diodes 400 sensing red R, green G, and blue B signals on the photo diode region thereof.

Next, interlayer dielectric layer 200 may be formed on semiconductor substrate 100 formed with the plurality of photo diodes 400, and the R, G, and B color filter layers 300 may be formed thereon. According to embodiments, color filter layers 300 may be formed in a mosaic form and formed to correspond to the R, G, and B photo diodes in drawing of color.

According to embodiments, blue photo resist may be coated and then patterned using a photo etching process to form B-color filter layer 300B at the position corresponding to a B-photo diode. Red photo resist may be coated on a surface, for example, the whole surface, including the B-color filter layer and then patterned using a photo etching process. This may form R-color filter layer 300R at the position corresponding to a R-photo diode. Green photo resist may be coated on a surface, for example, the whole surface, including R and B-color filter layers 300R and 30013 and then patterned using a photo etching process to form G-color filter layer 300G at the position corresponding to a G-photo diode.

However, when the green photo resist may be coated, due to a step between a portion where the R and B-color filter layers may be formed and a portion where the R and B-color filter layers are not formed, a concave curved surface may be formed on the surface of the green photo resist in the portion where the R and B-color filter layers are not formed and the concave curved surface may also remain on the patterned G-color filter layer. This may cause the surface steps of the RGB-color filter layers to become uneven.

Sacrifice layer 250 may then be formed by coating organic material such as a photo resist type or depositing inorganic material such as oxide film and nitride film, etc., having lower etching selectivity than the color filter layers on a surface, for example, the whole surface, including color filter layers 300. The sacrifice layer, which may be formed to make the uneven surface steps of the RGB color filter layers even, may be removed in a subsequent etching process.

Referring to FIG. 4b, sacrifice layer 250 may be dry etched until the upper surfaces of the color filter layers may be exposed by performing an etch back process.

Referring to FIG. 4c, upper surfaces of the RGB color filter layers 300 may be etched until any sacrifice layer 250 remaining between the color filter layers may be removed. According to embodiments, the etching selectivity between the color filter layers and the sacrifice layer and the etching selectivity between the color filter layers and the color filter layers may be low. The flat structure at the time of forming the sacrifice layer may be transcribed into the color filter layers as it is so that the surfaces of the color filter layers become flat when the sacrifice layer may be completely removed.

According to embodiments, to etch the upper surfaces of the color filter layers and the sacrifice layer, a reactive ion etching (RIE) etch back process, for example using oxygen (O₂) plasma, may be performed. According to embodiments, the step between the color filter layer patterns and the curved surface structure of the color filter layers may be relieved so that the surfaces of the color filter layers may be planarized.

Referring to FIG. 4d, mircolenses 500 may be directly formed without forming a separate planarization layer on color filter layers 300. According to embodiments, material having insulating characteristics and transmitting light may be coated and then patterned in a trapezoid shape using a photo etching process on a surface, for example, the whole surface, including the color filter layers According to embodiments, this may form the plurality of microlenses 500.

According to embodiments, microlenses 500, which may have a trapezoid shape, may be heated up to a melting point and then reflowed. This may cause their upper edges may be rounded. According to embodiments, the microlenses may be reflowed so that the gap between the microlenses may be minimized. However, the curvature thereof should be noticed not to be small to the extent that light cannot be focused by excessively reflowing the microlenses.

Also, although not shown in the drawing, passivation layer (not shown) may be formed on a surface, for example, the entire surface, including microlenses 500. Passivation layer may also be formed between microlenses 500 and RGB color filter layers 300. According to embodiments, the passivation layer may be formed of organic material or inorganic material.

According to embodiments, microlenses may be formed without adding a planarization layer on the color filter layers. Also, since the planarization layer may not be provided, embodiments may optimize the focal length for example by controlling the thickness of the color filter layers or the thickness of the microlenses.

According to embodiments, a method for manufacturing an image sensor may form color filter layers to be flat so that there may be no need to form a planarization layer to overcome the surface steps of the color filter layers. According to embodiments, since a separate process for forming the planarization layer may not be required, the process may be simplified and the manufacturing costs may be reduced.

According to embodiments, after the color filter layers may be formed, microlenses may be directly formed thereon without adding the planarization layer so that there may be no concern regarding degradation of light signal sensitivity due to the thick planarization layer and the microlenses may be formed with a sufficient thickness without the need to thinly form the microlenses to compensate for the focal length by the planarization layer thickness.

It will be apparent to those skilled in the art that various modifications and variations may be made to embodiments. Thus, it is intended that embodiments cover modifications and variations thereof within the scope of the appended claims. It is also understood that when a layer is referred to as being “on” or “over” another layer or substrate, it may be directly on the other layer or substrate, or intervening layers may also be present.

What is claimed is:

1. A method, comprising:
forming an interlayer dielectric layer over a semiconductor substrate having a plurality of photo diodes;
forming color filter layers over the interlayer dielectric layer;
forming a sacrifice layer over the semiconductor substrate, including the color filter layers;
etching upper surfaces of the color filter layers and the sacrifice layer to make step differences of the color filter layers even; and
forming microlenses over the color filter layers.

2. The method of claim 1, wherein the sacrifice layer comprises one of organic material and inorganic material.

3. The method of claim 1, wherein the sacrifice layer comprises material having low etching selectivity between the sacrifice layer and the color filter layers.

4. The method of claim 1, wherein an insulating layer is not provided between the color filter layers and the microlenses.

5. The method of claim 1, wherein upper surfaces of the color filter layers and the sacrifice layer are etched using an etch back process.

6. The method of claim 1, wherein upper surfaces of the color filter layers and the sacrifice layer are etched using a reactive ion etch (RIE) process using oxygen plasma.

7. The method of claim 1, wherein forming the color filter layers comprises:
forming a R-color filter layer by coating and patterning a first resist over the interlayer dielectric layer;
forming a B-color filter layer by coating and patterning a second resist over the R-color filter layer; and
forming a G-color filter layer by coating and patterning a third resist over the R and B-color filter layers.

8. The method of claim 1, further comprising forming a passivation layer over the surface including the microlenses.

9. The method of claim 1, further comprising forming a passivation layer between the microlenses and the color filter layers.

10. The method of claim 9, wherein the passivation layer comprises at least one of an organic material and an inorganic material.

11. A device, comprising:
a semiconductor substrate having a plurality of photo diodes;
an interlayer dielectric layer over the semiconductor substrate;
color filter layers over the interlayer dielectric layer;
a sacrifice layer over the color filter layers; and
a plurality microlenses over the color filter layers, wherein upper surfaces of the color filter layers and the sacrifice layer are etched to reduce step differences of the color filter.

12. The device of claim 11, wherein the sacrifice layer comprises at least one of an organic material and an inorganic material.

13. The device of claim 11, wherein the sacrifice layer comprises material having low etching selectivity between the sacrifice layer and the color filter layers.

14. The device of claim 11, wherein an insulating layer is not provided between the color filter layers and the microlenses.

15. The device of claim 11, further comprising a passivation layer between the microlenses and the color filter layers.

16. The device of claim 12, wherein the upper surfaces of the color filter layers and the sacrifice layer are etched using an etch back process.

17. The device of claim 12, wherein the color filter layers comprise R, G, B color filter layers.

18. A device, comprising:
a plurality of color filter layers over a semiconductor substrate;
a sacrifice layer over the color filter layers; and
a plurality microlenses over the color filter layers, wherein upper surfaces of the color filter layers and the sacrifice layer are etched to reduce step differences of the color filter.

19. The device of claim 18, wherein the sacrifice layer comprises material having low etching selectivity between the sacrifice layer and the color filter layers.

20. The device of claim 19, further comprising a passivation layer between the microlenses and the color filter layers, and wherein an insulating layer is not provided between the color filter layers and the microlenses.
